(19) United States
(12) Patent Application Publication
(10) Pub. No.: US 2016/0379926 A1
(43) Pub. Date: Dec. 29, 2016

(54) Semiconductor Wafer Backside Metallization With Improved Backside Metal Adhesion

(71) Applicant: Newport Fab, LLC dba Jazz Semiconductor, Inc., Newport Beach, CA (US)

(72) Inventors: David J. Howard, Irvine, CA (US); Hadi Jebory, Irvine, CA (US); Marco Racanelli, Santa Ana, CA (US)

(21) Appl. No.: 15/190,038

(22) Filed: Jun. 22, 2016

Related U.S. Application Data
(60) Provisional application No. 62/184,191, filed on Jun. 24, 2015.

(51) Int. Cl. H01L 23/528; H01L 23/532; H01L 21/02; H01L 21/304; H01L 21/768; H01L 29/06; H01L 23/48

(52) U.S. Cl. CPC H01L 23/528; H01L 29/0657; H01L 23/53223; H01L 23/53238; H01L 23/53252; H01L 23/481; H01L 21/304; H01L 21/76871; H01L 21/02068; H01L 21/76841; H01L 21/76898

(57) ABSTRACT

A method of fabricating a semiconductor structure includes: grinding a backside surface of a semiconductor substrate such that the backside surface has a relatively high average roughness (Ra) (when compared with a backside surface subjected to chemical mechanical polishing (CMP)), and then, forming a backside metal structure on the backside surface while the backside surface has the relatively high average roughness. The backside surface can have an average roughness in the range of about 5 to 100 nanometers (or alternately, in the range of about 20 to 40 nanometers) when the backside metal structure is formed. The backside metal structure may be electrically coupled to through silicon vias (TSVs), which supply ground to semiconductor devices fabricated on a front side of the semiconductor substrate.

### RELATED APPLICATION

The present application claims priority to U.S. Provisional Application Ser. No. 62/184,191, filed Jun. 24, 2015, which is incorporated herein by reference.

### FIELD OF THE INVENTION

The present invention relates to a semiconductor structure including a semiconductor substrate having devices fabricated on a front side, and an electrically conductive layer formed on the backside.

### RELATED ART

Semiconductor devices, such as complementary-metal-oxide semiconductor (CMOS) devices, complementary bipolar CMOS (BiCMOS) devices, bipolar junction transistors (BJTs) and field effect transistors (FETs), and microelectromechanical systems (MEMS) devices, that are fabricated on a front side of a semiconductor wafer, usually require conductive structures, such as through substrate vias (TSVs), to provide electrical connections to a backside metal structure on a backside of the semiconductor wafer. For example, low resistance electrical ground connections in integrated circuits, particularly for certain radio frequency (RF) devices, are required for proper device function. The electrical connections to the TSVs from the backside of the semiconductor wafer can be made by grinding the backside of the semiconductor wafer to reveal the vias that have been created in the wafer from the other side (frontside). Thereafter, the semiconductor wafer undergoes a chemical mechanical polishing (CMP) process to polish the backside surface to get a final smooth surface before the backside metal structure is formed thereon.

FIG. 1 illustrates a backside surface 102 of a thinned semiconductor wafer 100 after a coarse grind, a fine grind and a polishing (e.g., CMP) process have been completed, according to a conventional backside metallization preparation process. A plurality of TSVs, including TSVs 104, 106 and 108 are exposed on polished backside surface 102 of the thinned semiconductor wafer 100. As compared to a backside surface that has only been subjected one or more grinding processes, polished backside surface 102 has a very smooth surface. For example, polished backside surface 102 typically has an average roughness (Ra) of substantially less than 5 nm. Note that average roughness (Ra) is a conventional measurement, which is defined as the arithmetic average of the absolute values of the profile height deviations from the mean line, recorded within an evaluation length. Simply put, average roughness (Ra) is the average of a set of individual measurements of a surface's peaks and valleys. More specifically, average roughness (Ra) of a surface may be defined by the following equation:

$$Ra = \frac{1}{n} {\sum }_{i = 0}^{n} \vert Yi \vert$$

wherein n is a number of data points along a 2-dimensional (2D) roughness profile of the surface, and Yi is the vertical distance between the mean line of the 2D roughness profile and the i^{th} data point of the 2D roughness profile.

A backside metal structure (not shown) is formed on polished backside surface 102, thereby electrically connecting the various exposed TSVs. However, polished backside surface 102 may not provide good adhesion properties for the backside metal structure. To ensure high fabrication yields, the backside metal structure must remain securely attached to the semiconductor wafer throughout the entire fabrication process. However, fabrication procedures such as wafer handling (e.g., taping removing, contacting), semiconductor die singulation (e.g., dicing) and pick-and-place (e.g., vacuum tools) processes subject the semiconductor substrate to very high stresses, due to normal and/or shear forces exerted on the backside metal structure, for example, especially near the edges and/or corners of the semiconductor dies. Other factors, such as differences in coefficients of thermal expansion (CTE), may also lead to stress in the backside metal structure as the semiconductor wafer expands and contracts during subsequent thermal processes. As a result, the backside metal structure often ends up peeling off from the polished backside surface 102 of the semiconductor wafer 100 at the end of the fabrication process, leading to unacceptably low yields, such as 5-10% of die, or requirement to scrap the entire wafer. Thus, there is a need in the art for a robust backside metallization process to improve backside metal adhesion to the semiconductor wafer and achieve high yields.

### SUMMARY

Accordingly, the present invention provides an improved method for forming a metal structure on the backside of a semiconductor substrate that includes grinding a backside surface of a semiconductor substrate such that the backside surface has a relatively high average roughness (Ra) (when compared with a backside surface subjected to chemical mechanical polishing (CMP)). In one embodiment, the backside surface has an average roughness in the range of about 5 to 100 nanometers. In another embodiment, the backside surface has an average roughness in the range of about 20 to 40 nanometers. Grinding the backside surface can include performing a coarse grind, and then performing a fine grind. A backside metal structure is then formed on the rough backside surface of the semiconductor substrate. In accordance with various embodiments, the backside metal structure can include a seed layer, a barrier layer, and a low resistance (metal) layer. Forming the backside metal structure on the relatively rough backside surface of the semiconductor substrate advantageously improves adhesion of the backside metal structure, thereby improving yields. Because chemical mechanical polishing (CMP) is not performed on the backside surface of the semiconductor substrate, processing time and processing costs are advantageously reduced.

The present invention will be more fully understood in view of the following description and drawings.

### BRIEF DESCRIPTION OF THE DRAWINGS

FIG. 1 illustrates a polished backside surface of a semiconductor wafer, upon which a conventional backside metal structure is formed.

FIG. 2 is a flow diagram illustrating a method of fabricating a backside metal structure on the backside of a semiconductor substrate in accordance with various embodiments of the present invention.

FIGS. 3A, 3B, 3C and 3D are cross sectional views of a semiconductor structure during various stages of the method of FIG. 2.

FIG. 4 illustrates a rough backside surface of a semiconductor wafer, upon which a backside metal structure is formed in accordance with one embodiment of the present invention.

### DETAILED DESCRIPTION

The following description contains specific information pertaining to implementations in the present disclosure. The drawings in the present application and their accompanying detailed description are directed to merely exemplary implementations. Unless noted otherwise, like or corresponding elements among the figures may be indicated by like or corresponding reference numerals. Moreover, the drawings and illustrations in the present application are generally not to scale, and are not intended to correspond to actual relative dimensions.

In general, the present inventive concepts utilize a coarse grind, followed by a fine grind to create a rough surface finish on the backside of a semiconductor substrate (wafer), as opposed to a smooth surface finish achieved by a conventional polishing (e.g., CMP) process. In a departure from conventional backside metal formation processes, according to the present inventive concepts, the fine grind is a final action during the grinding process, thus eliminating the conventional polishing (e.g., CMP) process, resulting in the backside surface of the semiconductor substrate having an average roughness (Ra) of about 5 to 100 nm. Thereafter, a backside metal structure having a seed layer, a barrier layer and a low resistance layer, is formed on the rough backside surface of semiconductor substrate, where the roughness of the backside surface and the seed layer help improve adhesion of the backside metal structure to the semiconductor wafer, thus preventing peeling of the backside metal structure at the end of the fabrication process.

The present invention will now be described in more detail.

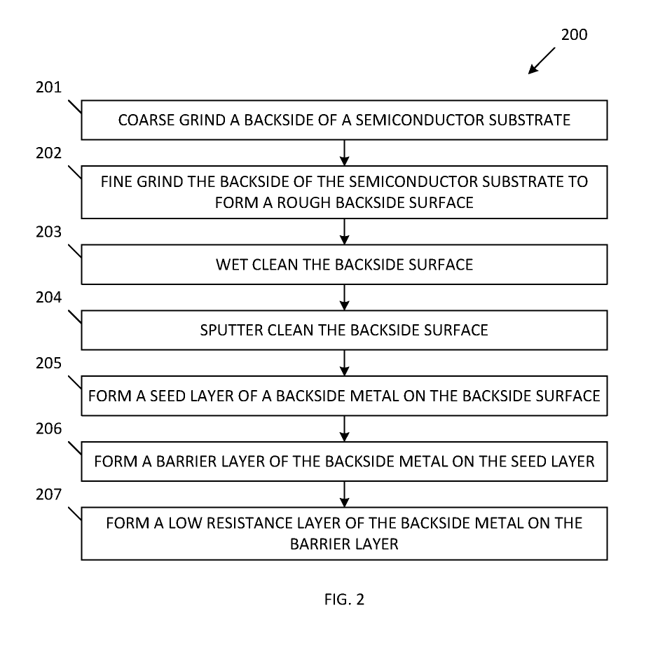

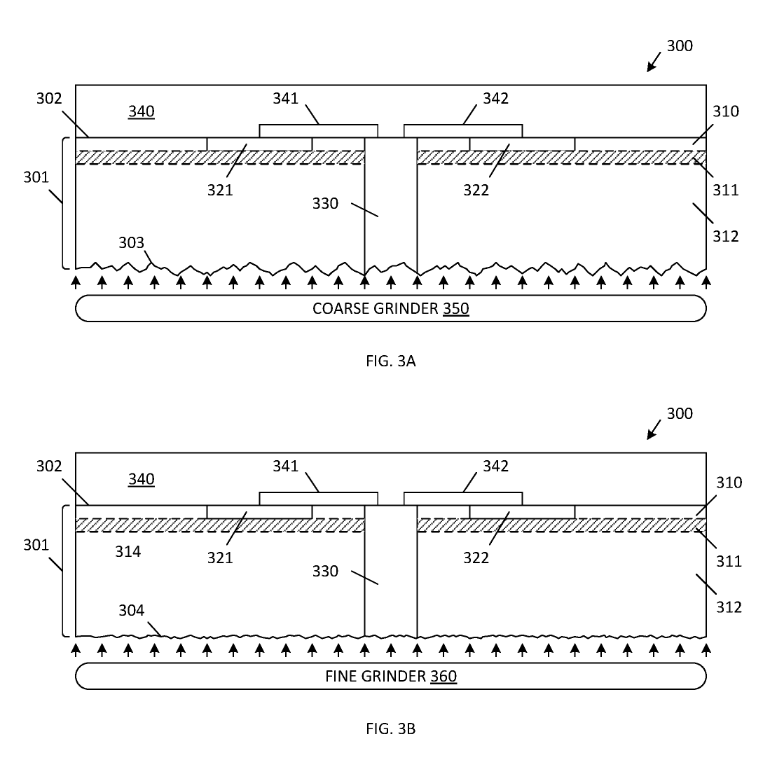

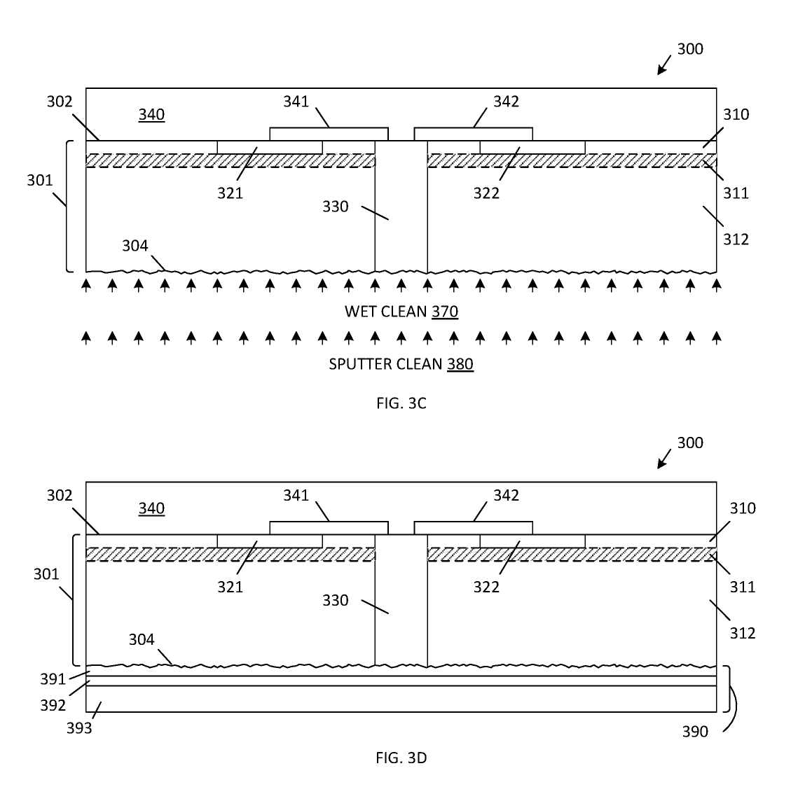

FIG. 2 is a flow diagram 200 illustrating a method of fabricating a backside metal structure on the backside of a semiconductor substrate in accordance with various embodiments of the present invention. FIGS. 3A-3D are cross sectional views of a semiconductor structure 300 during various stages of the method of FIG. 2.

Initially, a coarse grinding process is performed to the backside surface of a semiconductor substrate (FIG. 2, action 201). In the example illustrated by FIG. 3A, a semiconductor structure 300 includes a semiconductor substrate 301 and a multi-layer interconnect structure 340. A coarse grinder 350 is used to grind the backside surface 303 of the semiconductor substrate 301.

Semiconductor substrate 301 may include a continuous semiconductor structure (e.g., a monocrystalline silicon wafer). Alternately, as illustrated by FIG. 3A, semiconductor substrate 301 may include a silicon-on-insulator (SOI) construction, which includes thin semiconductor region 310, buried insulator layer 311 and underlying semiconductor region 312. Thus, as used herein, the term “semiconductor substrate” refers to any structure that includes a front side surface where conventional semiconductor devices are fabricated, and an opposing backside surface.

In the example of FIG. 3A, a plurality of semiconductor devices 321-322 are fabricated at the front side surface 302 of the semiconductor substrate 301 (which is located opposite the backside surface 303 of the semiconductor substrate 301). A through substrate via (TSV) 330 extends through the semiconductor substrate 301, between the front side surface 302 and the backside surface 303. Multi-layer interconnect structure 340 includes conductor structures 341 and 342, which electrically connect TSV 330 to semiconductor devices 321 and 322, respectively. In the embodiments described herein, TSV 330 provides a ground supply voltage to semiconductor devices 321-322 (via a subsequently formed backside metal structure 390).

At the conclusion of the coarse grinding process, the backside surface 303 of semiconductor substrate 301 has a relatively high average roughness (Ra). For example, the backside surface 303 of semiconductor substrate 301 may have an average roughness (Ra) greater than about 75 nm after the coarse grinding process.

After the coarse grinding process is complete, a fine grinding process (FIG. 2, action 202) is performed to the backside surface of the semiconductor substrate. In the example illustrated by FIG. 3B, a fine grinder 360 is used to grind the backside surface of semiconductor substrate 301. In general, fine grinder 360 has a finer grit than coarse grinder 350. At the conclusion of the fine grinding process, the backside surface 304 of semiconductor substrate 301 has a moderate average roughness (Ra). In accordance with one embodiment, the backside surface 304 of semiconductor substrate 301 has an average roughness (Ra) of approximately 5 to 100 nm at the end of the fine grinding process. In accordance with another embodiment, the backside surface 304 of semiconductor substrate 301 has an average roughness (Ra) of approximately 20 to 40 nm at the end of the fine grinding process.

After the fine grinding process is complete, a wet cleaning process is performed on the backside surface 304 of the semiconductor substrate 301 (FIG. 2, action 203). In one embodiment, the wet cleaning process is a water cleaning, performed by post-grind typical semiconductor wafer processing cleaning equipment that use de-ionized water, with or without surfactant, and usually involve a spray delivery system such that particles can be more effectively removed. FIG. 3C schematically illustrates the wet cleaning process 370. After the wet cleaning process is complete, semiconductor structure 300 may be optionally placed in a furnace for a low temperature baking process to dry the semiconductor substrate 301.

After the wet cleaning process is complete, a sputter clean process is performed on the backside surface 304 of the semiconductor substrate 301 (FIG. 2, action 204). FIG. 3C schematically illustrates the sputter clean process 380. In one embodiment, the sputter clean process is performed by placing the semiconductor structure 300 in a first chamber of a high vacuum tool. In the first chamber of the high vacuum tool, plasma sputtering may be performed to the semiconductor structure 300, for example, using argon atoms to loosen up the top few layers of atoms on the backside surface 304 of the semiconductor substrate 301, and to remove any oxidized silicon on the backside surface 304. For example, when a silicon wafer is exposed in the air for a period of time, the exposed silicon can be oxidized in room air. The sputter clean process 380 cleans the backside surface 304 to give the semiconductor substrate 301 a softer surface/edge for the subsequent metal deposition to improve adhesion, for example, between the silicon semiconductor substrate 301 and the subsequently deposited backside metal structure.

In a departure from conventional backside metal formation processing steps, the fine grind (202) is the final action during the grinding process, thus eliminating the conventional polishing (e.g., CMP) process, resulting in the backside surface 304 of the semiconductor substrate 301 having an average roughness (Ra) between a mirror and matte finish (e.g., Ra=20 to 40 nm). In alternate embodiments, the average roughness Ra of backside surface 304 is not so limited, and may have an average roughness outside this range, according to the requirements of a particular application. For example, in another implementation, backside surface 304 may have an average roughness (Ra) between 5 and 100 nm.

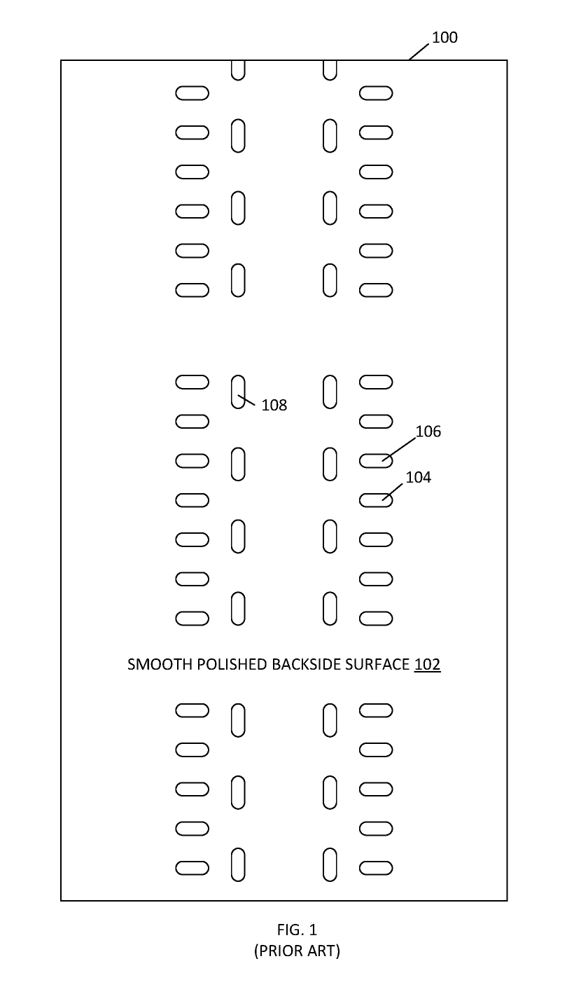

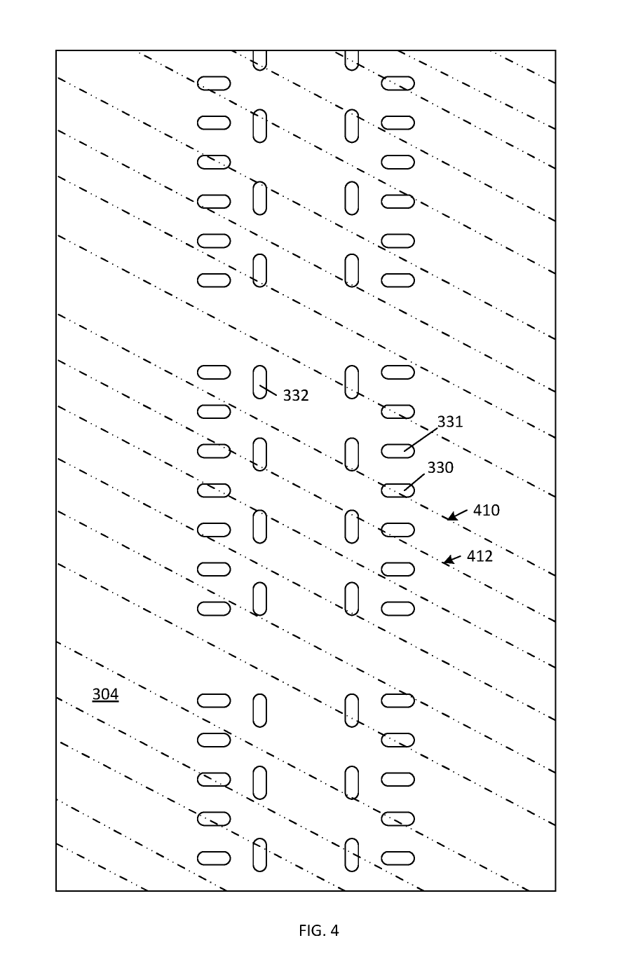

FIG. 4 illustrates the backside surface 304 of the thinned semiconductor substrate 301 after the coarse grind (201), fine grind (202), wet cleaning (203) and sputter cleaning (204) have been completed. As mentioned above, a polishing (e.g., CMP) process is not performed on the backside surface 304, such that the backside surface 304 has a higher average roughness than the conventional polished backside surface 102 of FIG. 1. A plurality of TSVs, including exemplary TSVs 330, 331 and 332 are exposed on the rough (unpolished) backside surface 304 of the thinned semiconductor substrate 301. As illustrated in FIG. 4, backside surface 304 is a rough surface, having a plurality of scratches, including exemplary scratches 410 and 412, as a result of the fine grind (202). These scratches provide for the improved adhesion of subsequently formed backside metal structure. Although the shapes of the TSVs illustrated by FIG. 4 are generally rectangular with rounded corners, it is understood that the TSVs can have other shapes in other embodiments, including, but not limited to, rectangular, octagonal or elliptical.

After the sputter clean is complete, the semiconductor structure 300 is transferred to a second chamber of the high vacuum tool, and a seed layer is deposited on the backside surface 304 (FIG. 2, action 205). As illustrated by FIG. 3D, seed layer 391 is formed over the backside surface 304. Seed layer 391 can include, for example, titanium (Ti) or titanium tungsten (TiW). In a particular embodiment, seed layer 391 is deposited to a thickness in the range of about 50 to 500 Angstroms. Seed layer 391 promotes adhesion between the backside surface 304 of semiconductor substrate 301 and the subsequently formed metal layers.

After the seed layer 391 has been deposited, the semiconductor structure 300 can remain in the second chamber of the high vacuum tool, or be transferred to a third chamber of the high vacuum tool, wherein a barrier layer is deposited on the seed layer 391 (FIG. 2, action 206). As illustrated by FIG. 3D, barrier layer 392 is formed over seed layer 391. Barrier layer 392 can include, for example, nickel-vanadium (NiV) or titanium-tungsten (TiW). In a particular embodiment, barrier layer is deposited to a thickness in the range of about 100-500 Angstroms. Barrier layer 392 prevents the subsequently formed low resistance metal layer 393 from contacting semiconductor substrate 301.

After the barrier layer 392 has been deposited, the semiconductor structure 300 can be transferred to another chamber of the high vacuum tool (e.g., a third chamber), wherein a low resistance layer (i.e., a thick metal layer) is deposited on the barrier layer 392 (FIG. 2, action 207). As illustrated by FIG. 3D, low resistance layer 393 is deposited over barrier layer 392. Low resistance layer 393 can include, for example, one or more high conductivity materials, such as copper (Cu), silver (Ag) and gold (Au). In a particular embodiment, low resistance layer 393 is deposited to a thickness in the range of about 1000 Angstroms to several microns. Although specific thicknesses have been provided for each of the layers 391-393, it is understood that the invention is not limited by these recited thicknesses, and that each of the layers 391-393 may have a thickness outside the above-mentioned ranges, according to the requirements of particular applications. Seed layer 391, barrier layer 392 and low resistance layer 393 combine to form backside metal structure 390, which (along with TSV 330) provide a ground voltage for the semiconductor devices 321-322 formed on the front side surface 302 of semiconductor substrate 301. Note that the backside metal structure 390 electrically connects the various exposed TSVs (including TSVs 330-332) on the backside surface 304 of semiconductor substrate 301.

In various alternate embodiments, the backside metal structure 390 need not include each of the seed layer 391 and the barrier layer 392. For example, in one embodiment, backside metal structure 390 may omit seed layer 391, and include only barrier layer 392 and low resistance layer 393. In another embodiment, backside metal structure 390 may omit both seed layer 391 and barrier layer 392, and include only low resistance layer 393.

Among other advantages, the present inventive concepts result in a cost effective backside metallization process with a short cycle time, and effectively eliminate the need for a conventional CMP process and additional anneal processes post metal deposition. For example, a semiconductor wafer under the present inventive methods can produce more than 50,000 good packages out of 60,000 singulated semiconductor dies from a semiconductor wafer (e.g., 90% yield), which represents a significant yield with respect to the prior art.

From the above description it is manifest that various techniques can be used for implementing the concepts described in the present application without departing from the scope of those concepts. Moreover, while the concepts have been described with specific reference to certain implementations, a person of ordinary skill in the art would recognize that changes can be made in form and detail without departing from the scope of those concepts. As such, the described implementations are to be considered in all respects as illustrative and not restrictive. It should also be understood that the present application is not limited to the particular implementations described above, but many rearrangements, modifications, and substitutions are possible without departing from the scope of the present disclosure. Thus, the present invention is intended to be limited only by the following claims.

We claim:

1. A semiconductor structure comprising:
a semiconductor substrate having a front side and a back side surface, wherein one or more semiconductor devices are fabricated at the front side, and wherein the back side surface has an average roughness in the range of about 5 to 100 nanometers; and
a backside metal structure formed on the back side surface of the semiconductor substrate.

2. The semiconductor structure of claim 1, wherein the back side surface has an average roughness in the range of about 20 to 40 nanometers.

3. The semiconductor structure of claim 1, wherein the backside metal structure comprises a seed layer deposited on the back side surface of the semiconductor substrate.

4. The semiconductor structure of claim 3, wherein the seed layer comprises titanium.

5. The semiconductor structure of claim 3, wherein the seed layer comprises titanium-tungsten.

6. The semiconductor structure of claim 3, wherein the seed layer has a thickness of about 50-500 Angstroms.

7. The semiconductor structure of claim 3, wherein the backside metal structure further comprises a barrier layer formed on the seed layer.

8. The semiconductor structure of claim 7, wherein the barrier layer comprises nickel-vanadium.

9. The semiconductor structure of claim 7, wherein the barrier layer comprises titanium-tungsten.

10. The semiconductor structure of claim 7, wherein the barrier layer has a thickness of about 100-500 Angstroms.

11. The semiconductor structure of claim 7, wherein the backside metal structure further comprises a metal layer formed on the barrier layer.

12. The semiconductor structure of claim 12, wherein the metal layer comprises at least one of copper, aluminum or gold.

13. The semiconductor structure of claim 12, wherein the metal layer has a thickness of at least about 1000 Angstroms.

14. The semiconductor structure of claim 1, further comprising one or more through substrate vias (TSVs) that extend through the semiconductor substrate, wherein the TSVs electrically couple the backside metal structure to at least one of the one or more semiconductor devices.

15. A method of fabricating a semiconductor structure comprising:
grinding a backside surface of a semiconductor substrate such that the backside surface has an average roughness in the range of about 5 to 100 nanometers; and then
forming a backside metal structure on the backside surface while the backside surface has an average roughness in the range of about 5 to 100 nanometers.

16. The method of claim 15, further comprising performing a wet clean of the backside surface after grinding the backside surface, and before forming the backside metal structure.

17. The method of claim 16, further comprising performing a sputter clean of the backside surface after performing the wet clean, and before forming the backside metal structure.

18. The method of claim 15, wherein forming the backside metal structure comprises forming a seed layer on the backside surface while the backside surface has an average roughness in the range of about 5 to 100 nanometers.

19. The method of claim 18, wherein forming the seed layer comprises depositing titanium or titanium-tungsten on the backside surface.

20. The method of claim 18, wherein forming the metal backside metal structure further comprises forming a barrier layer on the seed layer.

21. The method of claim 20, wherein forming the barrier layer comprises depositing vanadium-nickel or titanium-tungsten on the seed layer.

22. The method of claim 20, further comprising forming a metal layer on the barrier layer.

23. The method of claim 22, wherein forming the metal layer comprises depositing copper, aluminum or gold on the barrier layer.

24. The method of claim 15, wherein grinding the backside surface of the semiconductor substrate comprises:
performing a coarse grind on the backside of the semiconductor substrate; and then
performing a fine grind on the backside of the semiconductor substrate.

25. The method of claim 15, further comprising:
forming one or more through substrate vias (TSVs) that extend through the semiconductor substrate, wherein the TSVs electrically couple the backside metal structure to a semiconductor device at a front side of the semiconductor substrate.

26. The method of claim 15, wherein the grinding results in the backside surface having an average roughness in the range of about 20 to 40 nanometers, and wherein the backside metal structure is formed while the backside surface has an average roughness of about 20 to 40 nanometers.
